(19) United States
(12) Patent Application Publication
(10) Pub. No.: US 2025/0391781 A1
(43) Pub. Date: Dec. 25, 2025

(54) DUAL-SIGNATURE STRUCTURE TO VERIFY AUTHENTICITY IN MICROELECTRONICS

(71) Applicant: International Business Machines Corporation, Armonk, NY (US)

(72) Inventors: Viswas PUROHIT, East Amherst, NY (US); Junwon HAN, Loudonville, NY (US); Aakrati JAIN, Albany, NY (US); Kishan JAYANAND, Cohoes, NY (US); Mary MCGAHAY, Troy, NY (US); Nicholas LATHAM, Albany, NY (US); Sathyanarayanan RAGHAVAN, Ballston Lake, NY (US); Nicholas Alexander POLOMOFF, Hopewell Junction, NY (US)

(21) Appl. No.: 18/753,286

(22) Filed: Jun. 25, 2024

(51) Int. Cl. H01L 23/544; H01L 23/31

(52) U.S. Cl. CPC H01L 23/544; H01L 23/315; H10D 1/20; H01L 2223/54433

(57) ABSTRACT

Embodiments presented in this disclosure generally relate to anti-counterfeiting in microelectronics. More specifically, embodiments disclosed herein are directed to an integrated circuits (IC) with authenticity validation structures. One embodiment includes an IC, and a molding compound containing the IC, where the molding compound comprises a channel. A mixture is placed within the channel, where the mixture comprises one or more magnetic particles that provide an inductive signature for identifying the package.

### BACKGROUND

The present disclosure relates to anti-counterfeiting in microelectronics, and, more specifically, embodiments disclosed herein are directed to a structure that verifies the authenticity of integrated circuits (ICs) using dual signatures generated from inductive field responses and thermal measurements.

Counterfeiting electronic components present significant risks, including performance degradation, reliability issues, security vulnerabilities, and financial losses affecting both manufacturers and consumers. Several techniques are currently used to combat counterfeiting in the microelectronics industry, such as watermarking, holographic labels, electronic chip identifications (IDs), cryptography, Physical Unclonable Functions (PUFs), and supply chain controls. However, each method has its limitations. For example, watermarks and holographic labels are often superficial and can be replicated or removed by skilled counterfeiters. Electronic chip IDs are vulnerable to cloning and replicating, especially if counterfeiters have access to advanced technology and insider information. Cryptographic approaches, while powerful, increase complexity and cost, and depend on secure digital infrastructure for key management, which may not be available or feasible in all scenarios. These challenges highlight the needs for the development of more robust anti-counterfeiting solutions with broader feasibility.

### SUMMARY

One embodiment presented in this disclosure provides a package. The package comprises an integrated circuit (IC), and a molding compound containing the IC, where the molding compound comprises a channel. A mixture is placed within the channel, where the mixture comprises one or more magnetic particles that provide an inductive signature for identifying the package. One advantage provided by such an embodiment is the improved IC's security and enhanced accuracy of IC authentication against counterfeiting.

One embodiment presented in this disclosure provides a method for verifying the authenticity of a chip. The method generally includes fabricating a molding compound in which an IC is embedded, placing a mixture within the channel, the mixture comprising one or more magnetic particles, applying an alternating magnetic field to the chip to induce one or more electrical signals, generating an inductive signature based on the one or more electrical signals, and recording the inductive signature for authentication. One advantage provided by such an embodiment is the improved IC's security and enhanced accuracy of IC authentication against counterfeiting.

One embodiment presented in this disclosure provides an apparatus for verifying the authenticity of a chip. The apparatus generally includes a molding compound containing the chip, where the molding compound comprises a channel. A mixture is placed within the channel, where the mixture comprises at least one of one or more magnetic particles and one or more thermally conductive particles that are different from the one or more magnetic particles. One advantage provided by such an embodiment is facilitating dual-signature verification, effective improving the accuracy of IC authentication against counterfeiting.

### BRIEF DESCRIPTION OF THE DRAWINGS

FIG. 1 depicts an example integrated circuit (IC) with an embedded authenticity validation structure, according to some embodiments of the present disclosure.

FIGS. 2A-2D depict detailed views of an example authenticity validation structure, according to some embodiments of the present disclosure.

FIG. 3 depicts an example dual-signature authentication device, according to some embodiments of the present disclosure.

FIG. 4 depicts an example method for integrating authenticity validation structures into IC packaging and recording dual signatures during chip manufacturing, according to some embodiments of the present disclosure.

FIG. 5 depicts an example method for authenticating ICs using dual signatures during chip validation, according to some embodiments of the present disclosure.

FIG. 6 is a flow diagram depicting an example method for IC authenticity validation, according to some embodiments of the present disclosure.

### DETAILED DESCRIPTION

One embodiment presented in this disclosure provides a package. The package comprises an integrated circuit (IC), and a molding compound containing the IC, where the molding compound comprises a channel. A mixture is placed within the channel, where the mixture comprises one or more magnetic particles that provide an inductive signature for identifying the package. One advantage provided by such an embodiment is the improved IC's security and enhanced accuracy of IC authentication against counterfeiting.

In another embodiment, within the package, an interaction between the one or more magnetic particles and an external alternating magnetic field may induce one or more electrical signals, the one or more electrical signals may form the inductive signature of the IC, and the inductive signature may be compared with a recorded inductive signature to ensure the IC is authentic. One advantage provided by such an embodiment is enhanced authenticity verification for ICs. The disclosed embodiment, which translates magnetic interactions into a unique inductive signature, provides a reliable and efficient mechanism for verifying the authenticity of ICs.

In another embodiment, the one or more magnetic particles may comprise one or more ferromagnetic nanoparticles. Due to nanoparticles' granular properties, one advantage provided by such an embodiment is the improved sensitivity and accuracy of inductive signature generation and verification.

In another embodiment, the mixture may comprise one or more thermally conductive particles that provide a thermal signature for identifying the package. In another embodiment, within the package, an interaction between the one or more magnetic particles and an external alternating magnetic field may generate heat, the one or more thermally conductive particles may dissipate the heat to form the thermal signature of the IC, and the thermal signature may be compared with a recorded thermal signature to ensure the IC is authentic. The inclusion of thermally conductive particles facilitates the generation and verification of thermal signatures, and therefore improves security and accuracy of IC authentication against counterfeiting.

In another embodiment, the one or more thermally conductive particles may comprise one or more thermally conductive nanoparticles. Due to nanoparticles' granular properties, one advantage provided by such an embodiment is the improved sensitivity and accuracy of thermal signature generation and verification.

One embodiment presented in this disclosure provides a method for verifying the authenticity of a chip. The method generally includes fabricating a molding compound in which an IC is embedded, placing a mixture within the channel, the mixture comprising one or more magnetic particles, applying an alternating magnetic field to the chip to induce one or more electrical signals, generating an inductive signature based on the one or more electrical signals, and recording the inductive signature for authentication. One advantage provided by such an embodiment is the improved IC's security and enhanced accuracy of IC authentication against counterfeiting.

In another embodiment, the mixture may comprise one or more thermally conductive particles, and the method may further comprise generating a thermal signature by dissipating heat via the one or more thermally conductive particles, where the heat is generated in response to an interaction between the one or more magnetic particles and the alternating magnetic field, and recording the thermal signature for authentication. The disclosed embodiment facilitates the generation and verification of thermal signatures, and therefore improves security and accuracy of IC authentication against counterfeiting.

In another embodiment, the one or more electrical signals may be induced by an interaction between the one or more magnetic particles and the alternating magnetic field. The disclosed embodiment translates magnetic interactions into a unique inductive signature, providing a reliable and efficient mechanism for verifying the authenticity of ICs.

In another embodiment, the channel may comprise a spiral channel. The spiral shape of the channel can maximize (or at least increase) the surface area within the compact footprint, enhancing the interaction between the magnetic particles and the alternating magnetic field.

In another embodiment, the molding compound and the mixture may be enclosed within a packaging framework of the chip. One advantage of such an embodiment is facilitating effective and convenient authenticity verification without altering the internal circuit structure.

In another embodiment, the one or more magnetic particles may comprise one or more ferromagnetic nanoparticles. Due to nanoparticles' granular properties, one advantage provided by such an embodiment is the improved sensitivity and accuracy of inductive signature generation and verification.

In another embodiment, the one or more thermally conductive particles may comprise one or more thermally conductive nanoparticles. Due to nanoparticles' granular properties, one advantage provided by such an embodiment is the improved sensitivity and accuracy of thermal signature generation and verification.

One embodiment presented in this disclosure provides an apparatus for verifying the authenticity of a chip. The apparatus generally includes a molding compound containing the chip, where the molding compound comprises a channel. A mixture is placed within the channel, where the mixture comprises at least one of one or more magnetic particles and one or more thermally conductive particles that are different from the one or more magnetic particles. One advantage provided by such an embodiment is facilitating dual-signature verification, effective improving the accuracy of IC authentication against counterfeiting.

In another embodiment, the channel may comprise a spiral channel. The spiral shape of the channel can maximize (or at least increase) the surface area within the compact footprint, therefore enhancing the interaction between the magnetic particles and the alternating magnetic field.

In another embodiment, the one or more magnetic particles may provide an inductive signature for identifying the chip. In another embodiment, an interaction between the one or more magnetic particles and an external alternating magnetic field may induce one or more electrical signals, the one or more electrical signals may form the inductive signature of the chip, and the inductive signature can be compared with a recorded inductive signature to ensure the chip is authentic. One advantage provided by such embodiments is facilitating enhanced verification of IC authenticity using an inductive signature.

In another embodiments, the one or more thermally conductive particles may provide a thermal signature for identifying the chip. In another embodiment, an interaction between the one or more magnetic particles and an external alternating magnetic field may generate heat, the one or more thermally conductive particles may dissipate the heat to form the thermal signature of the chip, and the thermal signature may be compared with a recorded thermal signature to ensure the chip is authentic. One advantage provided by such embodiments is facilitating enhanced verification of IC authenticity using a thermal signature.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

With the increasing demand for electronic devices and the associated high manufacturing costs, there has been a significant rise in counterfeit ICs and other microelectronic components. These counterfeit components, once used, may risk the performance and reliability of electronic devices. There are several current anti-counterfeiting methods used, but each has limitations that cannot adequately address the growing challenges.

For example, watermarking and holographic labels involve embedding a unique pattern or label into the design of the IC that can be checked for authenticity. However, these measures are often superficial and can be replicated or removed by skilled counterfeiters. Electronic ID system involves using unique IDs embedded during manufacturing. While this can provide some level of protection, these IDs can sometimes be replicated or cloned, especially if the counterfeiter has access to advanced technology or insider information. Cryptographic technologies can offer robust security but also add complexity and significant cost, as they require a digital infrastructure for key management, making the technology not suitable for all types of devices. Physical Unclonable Functions (PUFs) exploit inherent and uncontrollable randomness in physical systems to create a unique identifier for each system. However, the technology is still an emerging field that lacks maturity, and its implementation can be complex. Supply chain controls involve carefully monitoring and controlling the supply chain to ensure that only genuine components are used. However, this method does not prevent counterfeiting, but rather aims to detect counterfeiting components before they are used.

The present disclosure introduces techniques and apparatus for anti-counterfeiting that integrate physical authentication features into the IC's packaging, combining inducement measurement and thermal detection to create a more robust and difficult-to-replicate authentication mechanism. In some embodiments, the physical authentication features may comprise a spiral grooved channel fabricated on or near a surface (e.g., on or slightly below the top surface) of the IC's packaging, filled with a mixture of nanoparticles. For example, the authentication features may be embedded below the surface of the package, near enough to the surface to ensure that the signatures can be accurately read. These nanoparticles may include ferromagnetic nanoparticles and thermally conductive nanoparticles. The ferromagnetic particles may interact with an external alternating magnetic field to produce an inductive signature. Additionally, heat may be generated during the interaction, and the heat dissipation through the thermally conductive nanoparticles may form a thermal signature. These dual signatures (inductive and thermal) may then be compared with recorded signatures to determine the authenticity of the IC.

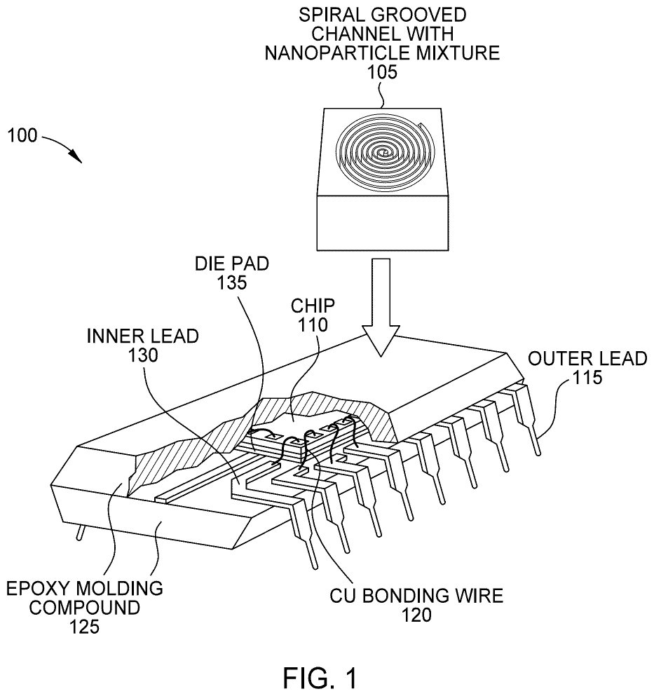

FIG. 1 depicts an example integrated circuit (IC) package 100 with an embedded authenticity validation structure 105, according to some embodiments of the present disclosure.

As illustrated, various microelectronic components are enclosed within the IC package 100. At the center is the chip 110 (also referred to in some embodiments as a semiconductor die or IC), which consists of integrated electronic circuits and is the primary active component within the IC package. The chip 110 is mounted on a die pad 135 that provides structural support. In some embodiments, the die pad 135 may be made of materials with good thermal conductivity, which helps to dissipate heat generated by the chip 110 during operation. The copper (Cu) bonding wires 120 provide electrical connections between the chip 110 and the inner leads 130. These inner leads 130 are then connected to the outer leads 115 to enable connections to external circuits on a circuit board. The chip 110 and the internal connections (including the die pad 135, the inner leads 130, and the outer lead 115) are enclosed within the epoxy molding compound 125, forming the IC package 100. In some embodiments, the epoxy molding compound 125 may protect the internal components from environmental and mechanical stresses, such as moisture, dust, chemical contaminants, and vibration. In some embodiments, the epoxy molding compound 125 may help dissipate heat generated by the chip 110 during operation.

As illustrated, an authenticity validation structure 105 is fabricated on the top surface of the epoxy molding compound 125. In some embodiments, the structure 105 may comprise a spiral grooved channel filled with a mixture of nanoparticles. The validation structure 105 may then be checked to verify the authenticity of the chip 110, acting as a security feature to prevent counterfeiting and ensure the device's integrity in its applications.

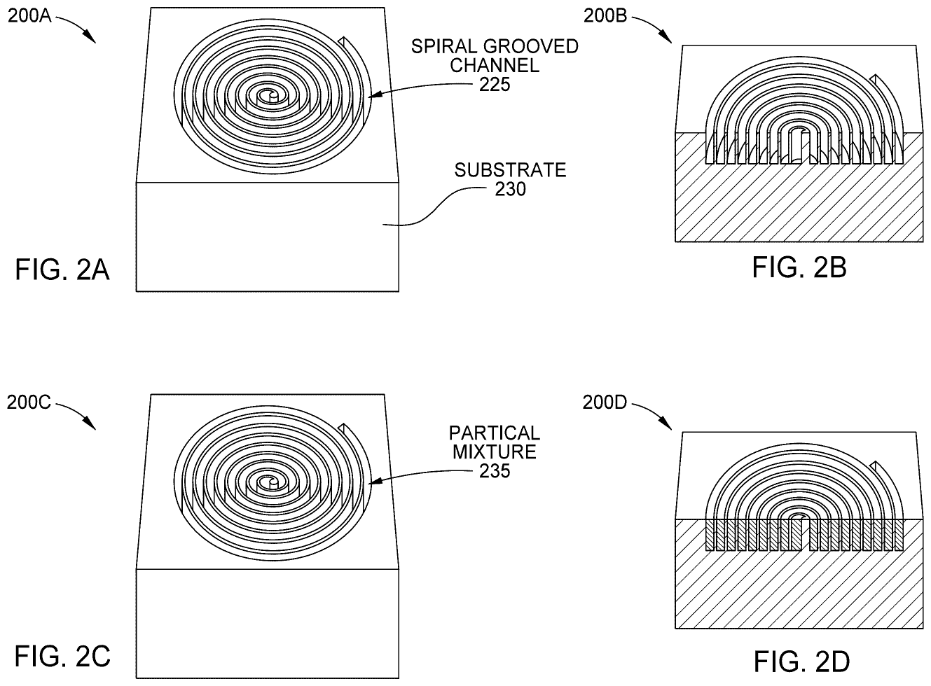

FIGS. 2A-2D depict detailed views of an example authenticity validation structure, according to some embodiments of the present disclosure. As illustrated, the authenticity validation structure comprises a spiral grooved channel 225 filled with a mixture of nanoparticles 235.

FIG. 2A depicts a top view 200A of the spiral grooved channel 225 on a substrate 230. In some embodiments, the substrate 230 may be positioned on the top surface of an IC's package (or it may form part of the top surface of the IC's package), making the channel easily accessible for authenticity validation. In some embodiments, the substrate 230 may correspond to the epoxy molding compound 125 as depicted in FIG. 1. The top view 200A clearly shows the layout and geometry of the channel 225. Although the illustrated example depicts a spiral grooved channel for conceptual clarity, in some aspects, other shaped channels may be used. Similarly, in some aspects, multiple channels may be used.

FIG. 2B depicts a cross-sectional view 200B of the same channel 225 on the substrate 230, which provides insights into the depth of the channel within the substrate. In some embodiments, the spiral grooved channel 225 may be 1 micrometer in width with a total diameter of 5 millimeters. In some embodiments, 1 micrometer in width may include a width of approximately 1 micrometers, falling within a range from 0.9 to 1.1 micrometers, or a range from 0.8 to 1.2 micrometers. In some embodiments, a total diameter of 5 millimeters may include a diameter of approximately 5 millimeters, falling within a range from 4.9 to 5.1 millimeters, or a range from 4.8 to 5.2 millimeters Although the illustrated example depicts the grooved channel having a static depth (e.g., each portion has the same depth in the substrate 230), in some aspects, the depth of the channel may vary across the substrate 230.

FIG. 2C depicts a top view 200C of the spiral grooved channel 225 after it has been filled with a mixture of particles 235. FIG. 2D depicts a cross-sectional view 200D of the channel 225 filled with the mixture 235. In some embodiments, the mixture of particles 235 may comprise ferromagnetic nanoparticles and thermally conductive nanoparticles. In some embodiments, the ferromagnetic nanoparticles may be selected for their magnetic properties, which enable the particles to generate a unique inductive signature when exposed to an alternating magnetic field. The inductive signature may then be used to verify the chip's authenticity. Additionally, the application of an alternating magnetic field to the ferromagnetic nanoparticles may induce hysteresis losses, leading to heat generation. In some embodiments, the thermally conductive nanoparticles may be incorporated to facilitate the dissipation of the heat towards the surface. Such heat dissipation may cause a measurable change in temperature detectable by a thermal scanner (like an infrared (IR) camera). In some embodiments, the detected temperature changes may create a thermal signature that can also be used to verify the authenticity of the chip.

The spiral grooved channel 225 is provided here for conceptual clarity. In some embodiments, other geometries may be fabricated as the embedded structure. These alternative geometries may also be designed for filling with nanoparticles 235, and used for dual-signature authentication.

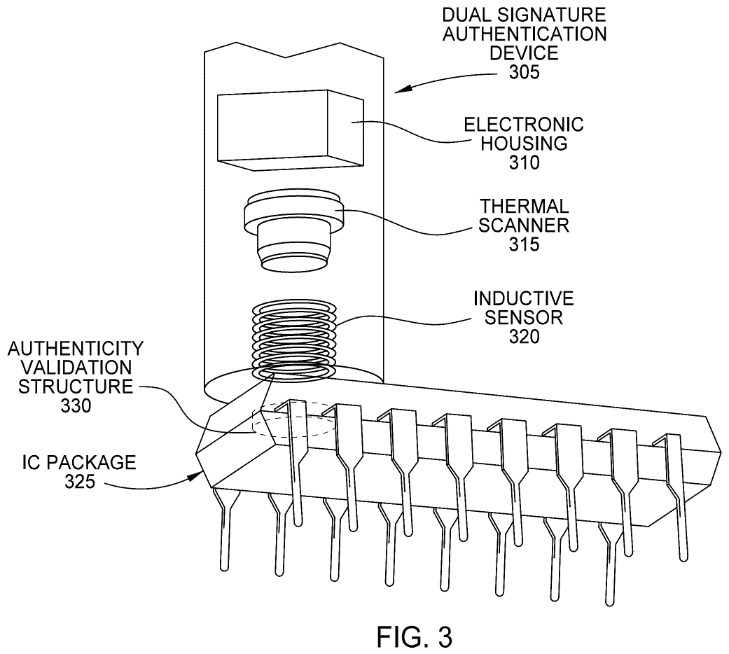

FIG. 3 depicts an example dual-signature authentication device 305, according to some embodiments of the present disclosure.

As illustrated, the dual-signature authentication device 305 comprises three components: the electronic housing 310, the thermal scanner 315, and an inductive sensor 320. In some embodiments, the electronic housing 310 may include control circuits and/or power supply units for the thermal scanner 315 and the inductive sensor 320, respectively. In some embodiments, the electronic housing 310 may also contain signal processing circuits that interpret data from the thermal scanner 315 and inductive sensor 320, and convert the data into inductive and thermal signatures for authentication purposes.

In some embodiments, the inductive sensor 320 may comprise an emitter coil antenna and a receiver coil antenna (or a single coil used for both emitting and receiving). As illustrated, the IC package 325 includes a chip (also referred to in some embodiments as IC), and a structure for authenticity validation 330. In some embodiments, the validation structure 330 may contain a spiral grooved channel (e.g., 225 of FIG. 2A) filled with a mixture of nanoparticles (e.g., 235 of FIG. 2C), including ferromagnetic nanoparticles and thermally conductive nanoparticles.

As depicted, when verifying the chip's authenticity, the dual-signature authentication device 305 is placed on top of IC package 325, specifically near the spiral grooved channel embedded within the IC package 325. In some embodiments, the emitter coil antenna within the inductive sensor 320 may generate an alternating magnetic field directed towards the grooved channel. The field may influence the ferromagnetic nanoparticles, altering their magnetic states and thus modifying the overall magnetic environment. These changes may induce a voltage in the receiver coil antenna within the inductive sensor 320, which is a direct result of electromagnetic induction caused by the altered magnetic fields. The voltage induced in the receiver coil antenna may then be converted into electrical signals, which are measured and analyzed to generate an inductive signature. In some embodiments, the inductive signature may reflect the unique electromagnetic pattern or response generated by the ferromagnetic nanoparticles within the IC package 325 when exposed to an alternating magnetic field. Changes in the signature may indicate physical changes or anomalies within the properties of the ferromagnetic nanoparticles. For ICs, chip manufacturers may design a unique inductive signature by selecting the composition, size, and distribution of the ferromagnetic nanoparticles, as well as the geometry and orientation of the embedded structure. During chip manufacturing, the inductive signature may be recorded and saved in a Chain of Custody document. During chip verification, the measured inductive signature may then be compared with the signatures recorded in the COC document to verify the authenticity of the chip.

The thermal scanner 315 is used to detect temperature changes on the surface of the authenticity validation structure 330 and/or IC package 325. In some embodiments, the thermal scanner 315 may include an infrared (IR) camera. In some embodiments, hysteresis losses may occur within the ferromagnetic nanoparticles due to their magnetic domain alignment and realignment in response to the applied external alternating magnetic field. The hysteresis losses may cause heat generation. The generated heat may then be dissipated via the thermally conductive nanoparticles towards the surface of the validation structure 330, causing measurable temperature changes captured by the thermal scanner 315. In some embodiments, the thermal scanner 315 may detect temperature changes per unit of time (e.g., seconds, minutes), and the data may then be used to generate a thermal signature. In some embodiments, the thermal signature may reflect the unique heat distribution and dissipation characteristics of the IC package 325. Changes in the thermal signature may indicate physical changes or anomalies within the properties of the nanoparticles and their distribution. Chip manufacturers may design a unique thermal signature by selecting specific types of ferromagnetic and thermally conductive nanoparticles, and/or adjusting their ratio and distribution within the layout of the validation structure. During chip manufacturing, the designed thermal signature may be recorded and saved in the COC document, along with the inductive signature. During the verification process, the measured thermal signature from the IC package 325 under test may then be compared with the recorded signature in the COC document.

In some embodiments, a dual-signature validation approach may be followed, where the IC package 325 is considered authentic only if both thermal and inductive signatures match the recorded ones. If either signature does not match, the IC package may be marked as counterfeit and reserved for further investigation. The dual-signature validation method may enhance the robustness and reliability of the authentication process by utilizing both inductive measurement and thermal responses. The method may not only reduce the likelihood of false positives but also increase the difficulty of counterfeiting. Additionally, the dual-signature validation method may further offer advantages in terms of cost and applicability across various types of chip designs. For example, the materials required for the validation structure, such as ferromagnetic and thermally conductive nanoparticles, are generally inexpensive and readily available. The integration of these nanoparticles involves modifications to the chip's substrate or packaging, which can be implemented during the regular fabrication phases. The manufacturing compatibility and readily available materials ensure that adding the validation structure does not introduce significant new costs or complexities.

In some embodiments, either the inductive signature or the thermal signatures may be used exclusively to verify the authenticity of the IC package. For example, in environments with significant thermal fluctuations, these fluctuations may adversely affect the accuracy of thermal signature measurements. Under such conditions, inductive signature may be relied exclusively on to determine the IC package's authenticity. In environments with high electromagnetic interference (EMI), such as in industrial areas with heavy machinery, EMI may disrupt the accuracy of inductive signature measurements. In this configuration, thermal signature may be relied exclusively on to determine the IC package's authenticity.

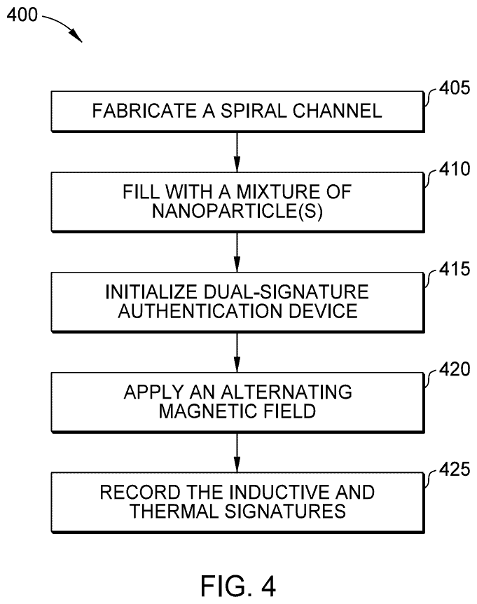

FIG. 4 depicts an example method 400 for integrating authenticity validation structures into IC packaging and recording dual signatures during chip manufacturing, according to some embodiments of the present disclosure.

The method 400 begins at block 405, where a chip manufacturer fabricates a spiral grooved channel (e.g., 225 of FIG. 2A) on the molding compound (e.g., 230 of FIG. 2A) of an IC package (e.g., 325 of FIG. 3). Various etching techniques may be used, such as photolithography or laser machining, to ensure the channel is aligned to specific dimensions designed to optimize functionality. In some embodiments, the spiral grooved channel may be 1 micrometer in width with a total diameter of 5 millimeters.

At block 410, the grooved channel is filled with a mixture of nanoparticles (e.g., 235 of FIG. 2C). In some embodiments, the mixture of nanoparticles may comprise ferromagnetic nanoparticles for magnetic responsiveness and thermally conductive nanoparticles to assist in heat dissipation. In some embodiments, the ferromagnetic nanoparticles may interact with an external alternating magnetic field to generate an inductive signature. The thermally conductive nanoparticle may dissipate heat generated during the interaction to produce a thermal signature. In some embodiments, to design unique signatures (inductive and thermal), the chip manufacturer may strategically select the composition, size, and distribution of the ferromagnetic and thermally conductive nanoparticles, as well as the geometry and orientation of the embedded structure.

At block 415, the chip manufacturer initializes and calibrates a dual-signature authentication device (e.g., 305 of FIG. 3) to interact with the nanoparticles embedded within the IC package (e.g., 325 of FIG. 3). In some embodiments, the dual-signature authentication device may comprise a thermal scanner (e.g., 315 of FIG. 3) and an inductive sensor (e.g., 320 of FIG. 3).

At block 420, an alternating magnetic field is applied to the IC package. In some embodiments, the inductive sensor may comprise an emitter coil antenna and a receiver coil antenna. The alternating magnetic field may be generated by the emitter coil antenna, which alters the magnetic states of the ferromagnetic nanoparticles and induces a voltage (or an electromotive force (EMF)) in the receiver coil antenna. In some embodiments, the magnitude and direction of the voltage may vary over time depending on the dynamics of the magnetic field interactions. The induced voltage may then be converted into electrical signals, which are processed to generate an inductive signature. Additionally, heat generated during the interactions may be dissipated by the thermally conductive nanoparticles towards the surface of the IC package. The temperature changes on the surface may be detected by the thermal scanner and generate a corresponding thermal signature.

At block 425, the chip manufacturer records the inductive and thermal signatures as reference signatures, and saves them in a COC document for future authentication use. Within the COC document, the inductive and thermal signatures may be associated with the chip manufacturer or a specific batch of chips produced by the manufacturer.

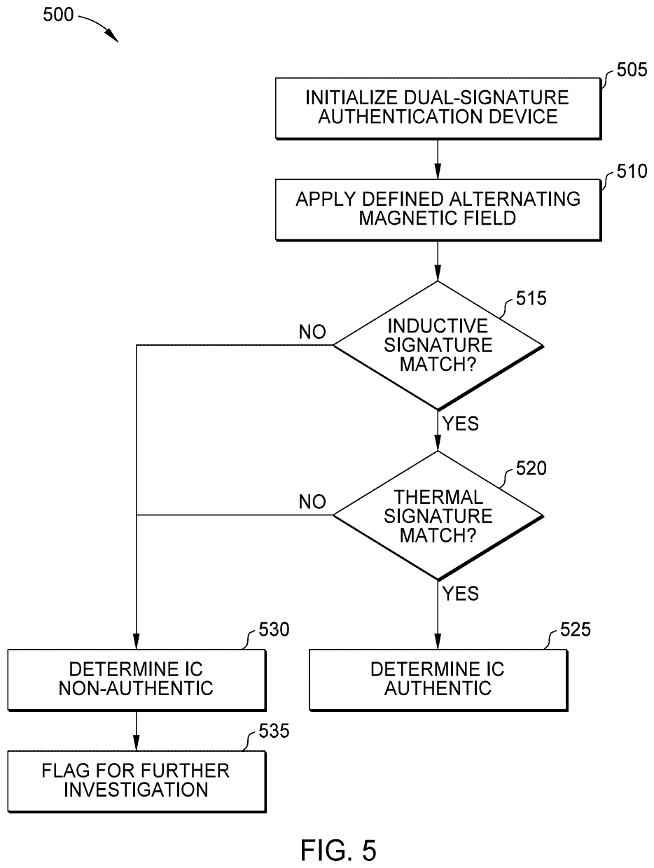

FIG. 5 depicts an example method 500 for authenticating ICs using dual signatures during chip validation, according to some embodiments of the present disclosure.

The method 500 begins at block 505, where a device manufacturer (or any other entity in the supply chain) receives an IC package (e.g., 325 of FIG. 3). In some embodiments, the IC package may comprise a spiral grooved channel (e.g., 225 of FIG. 2A) on its package, filled with ferromagnetic and thermally conductive nanoparticles (e.g., 235 of FIG. 2C). The device manufacturer initializes and calibrates a dual-signature authentication device (e.g., 305 of FIG. 3) to validate the authenticity of the IC package.

At block 510, an alternating magnetic field is applied towards the IC package. To ensure consistency and reliability, the characteristics of the alternating magnetic field (e.g., frequency, amplitude, and waveform) may be defined and recorded in the COC document, to ensure the field applied during chip validation is identical (or at least substantially similar) to the field used during chip manufacturing. In some embodiments, following the application, the alternating magnetic field may interact with the ferromagnetic nanoparticles within the spiral channel, altering their magnetic states and generating an inductive signature. In parallel, the interaction may result in heat generation due to hysteresis losses, creating a thermal signature.

At block 515, the inductive signature is compared against a recorded signature from an authentic IC package. In some embodiments, the inductive signature may include data on the magnitude and direction of the induced magnetic field. If the inductive signature matches the recorded reference, the method 500 proceeds to block 520. Otherwise, the method 500 proceeds to block 530, where the IC package is determined to be non-authentic. The IC package is then, at block 535, flagged for further investigation. In some embodiments, alerts may be sent to relevant parties within the supply chain to initiate corrective actions or further scrutiny.

At block 520, the thermal signature is compared against a recorded thermal signature from an authentic IC package. In some embodiments, the thermal signature may reflect the heat distribution and dissipation patterns of the IC package. If the thermal signature matches the recorded reference, the method 500 proceeds to block 525, where the IC package is confirmed as authentic. In some embodiments, if the recorded inductive and thermal signatures are associated with a specific chip manufacturer, the device manufacturer may then confirm the origin of the chip.

In some embodiments, minor discrepancies between the measured signatures and the recorded signatures may be acceptable. The minor discrepancies may occur due to environmental factors, inherent variances in production, or slight changes in material properties over time. In such configurations, a threshold may be set for the acceptable variance in the magnitude or phase of the inductive signature. For thermal signatures, a threshold may be established based on acceptable differences in temperature patterns and distributions. When signatures are compared at blocks 515 and 520, the IC package may be determined as authentic if both discrepancies fall within the acceptance ranges defined by the thresholds.

The example method 500 for authenticating chip using dual signatures is provided for conceptual clarity. In some embodiments, either an inductive signature or a thermal signature may be used exclusively to determine the authenticity of the chip. For example, in one embodiment, if the inductive signature matches the recorded signature at block 515, the method 500 may skip block 520 and move directly to block 525, where the IC package is confirmed as authentic. In another embodiment, following the generation of a thermal signature at block 510, the method 500 may skip block 515 and move directly to block 520. If the thermal signature matches the recorded signature at block 520, the method 500 may proceed to block 525, where the IC package is confirmed to be authentic.

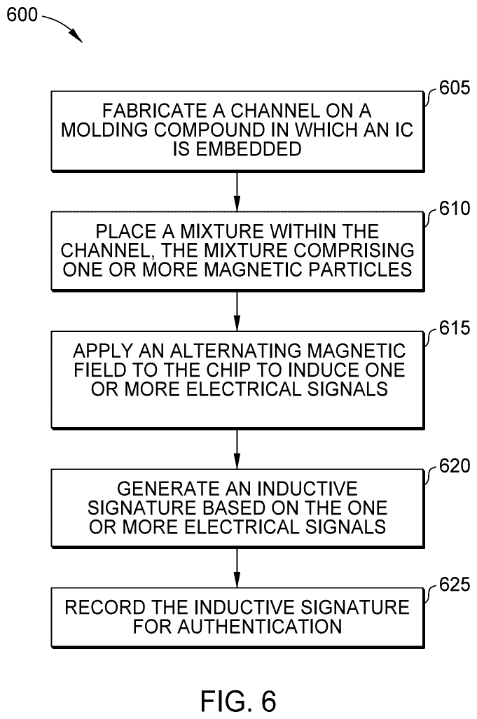

FIG. 6 is a flow diagram depicting an example method 600 for IC authenticity validation, according to some embodiments of the present disclosure.

At block 605, a channel (e.g., 225 of FIG. 2A) is fabricated on a molding compound in which an IC is embedded (e.g., 230 of FIG. 2A).

At block 610, a mixture (e.g., 235 of FIG. 2C) is placed within the channel, the mixture comprising one or more magnetic particles.

At block 615, an alternating magnetic field is applied to the chip to induce one or more electrical signals.

At block 620, an inductive signature is generated based on the one or more electrical signals.

At block 625, the inductive signature is recorded for authentication.

In some embodiments, the mixture may comprise one or more thermally conductive particles. In some embodiments, a thermal signature may be generated by dissipating heat via the one or more thermally conductive particles, where the heat is generated in response to an interaction between the one or more magnetic particles and the alternating magnetic field, and the thermal signature may be recorded for authentication.

In some embodiments, the one or more electrical signals may be induced by an interaction between the one or more magnetic particles and the alternating magnetic field. In some embodiments, the channel comprises a spiral channel.

In some embodiments, the molding compound and the mixture may be enclosed within a packaging framework of the chip.

In some embodiments, the one or more magnetic particles may comprise one or more ferromagnetic nanoparticles. In some embodiments, the one or more thermally conductive particles may comprise one or more thermally conductive nanoparticles.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

While the foregoing is directed to embodiments of the present disclosure, other and further embodiments of the disclosure may be devised without departing from the basic scope thereof, and the scope thereof is determined by the claims that follow.

What is claimed is:

1. A package, comprising:
an integrated circuit (IC);
a molding compound containing the IC, wherein the molding compound comprises a channel; and
a mixture placed within the channel, wherein the mixture comprises one or more magnetic particles that provide an inductive signature for identifying the package.

2. The package of claim 1, wherein:
an interaction between the one or more magnetic particles and an external alternating magnetic field induces one or more electrical signals;
the one or more electrical signals form the inductive signature of the IC; and
the inductive signature can be compared with a recorded inductive signature to ensure the IC is authentic.

3. The package of claim 1, wherein the one or more magnetic particles comprises one or more ferromagnetic nanoparticles.

4. The package of claim 1, wherein the mixture comprises one or more thermally conductive particles that provide a thermal signature for identifying the package.

5. The package of claim 4, wherein:
an interaction between the one or more magnetic particles and an external alternating magnetic field generates heat;
the one or more thermally conductive particles dissipate the heat to form the thermal signature of the IC; and
the thermal signature can be compared with a recorded thermal signature to ensure the IC is authentic.

6. The package of claim 4, wherein the one or more thermally conductive particles comprises one or more thermally conductive nanoparticles.

7. The package of claim 1, wherein the channel comprises a spiral channel.

8. A method for verifying an authenticity of a chip, comprising:
fabricating a channel in a molding compound in which an IC is embedded;
placing a mixture within the channel, the mixture comprising one or more magnetic particles;
applying an alternating magnetic field to the molding compound to induce one or more electrical signals;
generating an inductive signature based on the one or more electrical signals; and
recording the inductive signature for authentication.

9. The method of claim 8, wherein the mixture comprises one or more thermally conductive particles, the method further comprising:
generating a thermal signature by dissipating heat via the one or more thermally conductive particles, wherein the heat is generated in response to an interaction between the one or more magnetic particles and the alternating magnetic field; and
recording the thermal signature for authentication.

10. The method of claim 8, wherein the one or more electrical signals are induced by an interaction between the one or more magnetic particles and the alternating magnetic field.

11. The method of claim 8, wherein the channel comprises a spiral channel.

12. The method of claim 8, wherein the molding compound and the mixture are enclosed within a packaging framework of the chip.

13. The method of claim 8, wherein the one or more magnetic particles comprises one or more ferromagnetic nanoparticles.

14. The method of claim 9, wherein the one or more thermally conductive particles comprises one or more thermally conductive nanoparticles.

15. An apparatus for verifying an authenticity of a chip, comprising:
a molding compound containing the chip, wherein the molding compound comprises a channel; and
a mixture placed within the channel, wherein the mixture comprises at least one of one or more magnetic particles and one or more thermally conductive particles that are different from the one or more magnetic particles.

16. The apparatus of claim 15, wherein the channel comprises a spiral channel.

17. The apparatus of claim 15, wherein the one or more magnetic particles provide an inductive signature for identifying the chip.

18. The apparatus of claim 17, wherein:
an interaction between the one or more magnetic particles and an external alternating magnetic field induces one or more electrical signals;
the one or more electrical signals form the inductive signature of the chip; and
the inductive signature can be compared with a recorded inductive signature to ensure the chip is authentic.

19. The apparatus of claim 15, wherein the one or more thermally conductive particles provide a thermal signature for identifying the chip.

20. The apparatus of claim 19, wherein:
an interaction between the one or more magnetic particles and an external alternating magnetic field generates heat;
the one or more thermally conductive particles dissipate the heat to form the thermal signature of the chip; and
the thermal signature can be compared with a recorded thermal signature to ensure the chip is authentic.
